(19) United States
(12) Patent Application Publication
(10) Pub. No.: US 2007/0092751 A1
(43) Pub. Date: Apr. 26, 2007

(54) Plate for housing and/or lids for button cells and process for manufacturing such a plate

(76) Inventors: Hasso Haibach, Duisburg (DE); Peter Authur Boehmer, Zemmer/Rodt (DE)

Correspondence Address: STEVENS DAVIS MILLER & MOSHER, LLP, 1615 L STREET, NW, SUITE 850, WASHINGTON, DC, 20036, US

(21) Appl. No.: 10/567,827

(22) PCT Filed: Jul. 9, 2004
(86) PCT No.: PCT/EP04/07700

§ 371 Date: Jan. 3, 2007

(30) Foreign Application Priority Data
Aug. 13, 2003 (EP) 03077557.1

(51) Int. Cl. B32B 15/00; C23C 16/00; C25D 3/12; B32B 15/18

(52) U.S. Cl. 428/679; 427/248.1; 205/271

(57) ABSTRACT

The invention relates to a plate for producing housings and/or lids for button cell batteries, comprising a core layer of steel, a copper or nickel clad top layer at one side of the core layer and a nickel top layer at the other side of the core layer. The invention is characterized in that the nickel top layer has been applied by depositing the nickel and in that the core layer has a thickness from 0.10 to 0.5 mm. The invention also relates to a housing and lid for a button cell battery fabricated form such a plate, and to a process for manufacturing such a plate.

The invention relates to a plate for producing housings and/or lids for button cell batteries, the plate comprising a core layer of steel, a copper or a nickel top layer at one side of the core layer and a nickel top layer at the other side of the core layer. The invention also relates to a housing or lid for a button cell fabricated from such a plate, and to a process for manufacturing such a plate.

Housings and lids for button cell batteries are presently made from a stainless steel core layer having a clad nickel layer on the outside and a clad copper layer or clad nickel layer on the inside of the battery. The clad nickel layer on the outside of the housing and lid is present because the contact resistance of stainless steel is too high for battery purposes. Nickel is chosen in view of the outside appearance of the button cell battery. The clad copper layer is present on the inside of the housing or lid because the anode material (e.g. zinc powder with an alkaline electrolyte) in the button cell that contacts the housing or lid is chemically very aggressive and attacks metals other than pure copper by generating hydrogen, which could cause serious damage of cell due to explosion. A specifically chosen copper quality provides hydrogen overvoltage to prevent hydrogen generation. The clad nickel layer is present on the inside of the lid or housing because air holes of the button cell are exposed to aggressive chemicals and must be protected to ensure the foreseen lifetime of the battery. Currently stainless steel is used as core material in view of corrosion and strength requirements of the battery manufacturer.

The above described plate material of stainless steel core material with clad nickel and/or copper top layers has been used for a long time for producing housings and lids for button cell batteries. However, it has the drawback that this plate material is rather expensive.

It is an object of the invention to provide a plate for producing housings and/or lids for button cell batteries that is cheaper than the known stainless steel clad products for producing such housings and/or lids. It is another object of the invention to provide a process for manufacturing such plates.

According to a first aspect of the invention there is provided a plate for producing housings and/or lids for button cell batteries, comprising a core layer of steel, a copper or nickel clad top layer at one side of the core layer and a nickel top layer at the other side of the core layer, wherein the nickel top layer has been applied by depositing the nickel and wherein the core layer of steel has a thickness from 0.10 to 0.5 mm.

In comparison with the known stainless steel copper and/or nickel clad product the plate according to the invention has the advantage that the nickel layer that will form the outside of the housings and/or lids has not been clad on the core layer, but that the nickel has been deposited. Cladding is an expensive process, because a thin nickel foil must be rolled onto the core layer. The thin nickel foils are very expensive. To deposit nickel on a substrate is a process that is easier and cheaper. The core material has a thickness from 0.10 to 0.5 mm in view of the strength requirements of the battery manufacturer.

According to a preferred embodiment of the plate according to the invention, the nickel layer has been applied by plating, preferably electrolytic strip plating. Electrolytic strip plating is a well-known process for coating a substrate and forms a thin and well-defined layer on a substrate. Usually the nickel layer thus formed is not as pore-free as a clad layer because pin-holes can be present. According to the invention a sufficient thick nickel layer is deposited to ensure a pin-hole free nickel layer, which is rolled and diffusion annealed to provide a dense, homogeneous, ductile and corrosion resistant nickel/iron layer.

According to another embodiment of the plate according to the invention, the nickel layer has been applied by Physical Vapour Deposition (PVD) or by Chemical Vapour Deposition (CVD). PVD and CVD are at present not used on an industrial scale for coating strip material, but in view of the current developments in this field it is to be expected that these deposition methods can be used in the foreseeable future for coating a substrate in a cheaper way than cladding the substrate. PVD and CVD will then be a good alternative for plating to deposit nickel.

Preferably the plate consists of a core layer of steel, a copper or nickel clad layer on one surface of the core layer and a deposited nickel layer on the other surface of the core layer. No intermediate layers are present according to this preferred embodiment and the amount of deposited metals used is as low as possible.

According to another preferred embodiment, the plate consists of a core layer of steel, a deposited nickel layer on both surfaces of the core layer and a copper or nickel clad top layer on one of the nickel layers. Here a nickel layer is deposited on both surfaces of the core layer of steel.

In this case it is preferred if the nickel layer between the core layer of steel and the copper or nickel clad top layer is thinner than the deposited nickel top layer. When plating one side of a plate with nickel, the other side is also plated with a much thinner layer of nickel if no special measures are taken. The copper or nickel clad layer is present on this thin plated nickel layer.

The core layer of the plate can of course be made of stainless steel, as is the case in the known stainless steel copper and/or nickel clad product used for housings and lids for button cell batteries. However, according to a preferred embodiment the core layer consists of mild steel, preferably of deep drawing quality. Mild steel can be used because the risk that the lid will corrode is almost absent, since the nickel layer provides a good enough corrosion protection of the outer surface of the lid and the cutting edge of the lid is encapsulated in a plastic sealing ring between the drawn sidewall of the lid and the inside of the sidewall of the can of the button cell battery. Stainless steel is more expensive than mild steel, so the use of mild steel results in a mayor cost reduction. Mild steel has mechanical properties that are different from the mechanical properties of stainless steel, but that are good enough for housings and lids of button cells. To produce housings and lids with the form of a cup, the steel preferably has a deep drawing quality.

The plate could be produced with a thickness between 0.1 and 0.5 mm, preferably between 0.1 and 0.2 mm. This preferred thickness enhances the mechanical properties of the housings and lids made of this plate.

According to a second aspect of the invention there is provided a housing and a lid for a button cell battery fabricated from a plate according to the first aspect of the invention. The housings and lids for button cell batteries fabricated from this plate according to the invention are cheaper than the present housings and lids.

According to a third aspect of the invention there is provided a process for manufacturing a plate according to the first aspect of the invention, the process comprising the steps:
providing a hot rolled mild steel plate having a thickness between 0.7 and 5 mm, preferably 2.1 mm and
rolling the steel plate to a thickness of preferably 1.0 mm;
or:
providing a cold rolled mild steel plate having a preferred thickness of 1.0 mm;
depositing a nickel layer of 5 to 20 μm, preferably 10 μm thick on one side of the steel plate and optionally a nickel layer having a maximum thickness of 3 μm on the other side;
cladding a copper or nickel layer of 1 to 20%, preferably 5 to 10%, of the thickness of the steel plate on the other side of the steel plate;
rolling and annealing the steel plate to a thickness of 0.1 and 0.5 mm, preferably 0.1 and 0.2 mm.
   This process provides a plate for producing housings and/or lids for button cells that is cheaper than the known stainless steel copper and/or nickel clad product, due to the depositing of the nickel layer instead of the cladding of the nickel layer for the outside of the housings and lids as is necessary for the known stainless steel product.

To also deposit a nickel layer having a maximum thickness of 3 μm on the other side of the steel plate is advantageous when the nickel is deposited by plating, because the plating process of nickel on one side of the steel plate is easier when at the same time a thin nickel plated layer is formed on the other side of the steel plate.

According to one embodiment of the process, the mild steel plate having a thickness of preferably 1.0 mm is annealed before the nickel layer is deposited.

According to a preferred embodiment, the mild steel plate with the deposited nickel layer is diffusion annealed after the nickel layer has been deposited. This has the advantage that during annealing also diffusion takes place. This results in a stronger adhesion between the nickel and the steel plate, and in a ductile, homogeneous and highly corrosion resistant dense nickel iron alloy layer.

Preferably, the mild steel plate is annealed before the plate is rolled to its final thickness of 0.1 to 0.5 mm, preferably 0.1 to 0.2 mm. This results in an advantageous performance of the mild steel plate by generating the nickel iron containing diffusion layer.

According to one preferred embodiment of the method, the nickel is deposited using Physical Vapour Deposition (PVD) or Chemical Vapour Deposition (CVD). The advantages of the use of PVD and CVD have been elucidated above.

According to another preferred embodiment of the method, the nickel is deposited by plating, preferably electrolytic strip plating. The advantages of plating have been elucidated above.

The invention will be elucidated using the description of a preferred plate and a preferred process for manufacturing such a plate.

According to a preferred embodiment, the plate according to the invention consists of three layers. In the middle of the plate a core layer of mild steel is present. This mild steel is of deep drawing quality. The thickness of the core layer is preferably 0.1 to 0.2 mm. At one side of the core layer is present a deposited layer of nickel having a thickness of approximately 1 to 2 μm. At the other side of the core layer is present a clad copper or nickel layer having a thickness of approximately 5 to 30 μm. The total thickness of the plate is preferably 0.1 to 0.2 mm.

This plate can be directly used to fabricate housings (also called cans or cases) and/or lids for button cell batteries, by punching and drawing.

According to another preferred embodiment in addition to the three above mentioned layers, a deposited nickel layer is present between the s clad copper or nickel layer and the core layer. This nickel layer has a thickness of 0.1 to 3 μm, preferably 1 to 2 μm. This nickel layer has no consequence for the functionality of the housings and/or lids fabricated from this plate, in view of the presence of the copper or nickel clad top layer.

According to a preferred process for the manufacturing of the above plate, the following process steps are taken:
providing a hot rolled mild steel plate of deep drawing quality having a thickness of 0.7 to 5 mm, preferably 2.1 mm, which thickness is commercially available and
pickling the hot rolled steel plate and
cold rolling the steel plate to a thickness of approximately 1.0 mm;
or:
providing a cold rolled mild steel plate in deep drawing quality having a preferred thickness of 1.0 mm;
either: first annealing the steel plate and subsequently nickel plating a layer of approximately 10 μm on one side of the steel plate, or: first nickel plating a layer of approximately 10 μm on one side of the steel plate and subsequently diffusion annealing the plate;
cladding a copper or nickel layer of 1 to 20%, preferably 5 to 10%, of the thickness of the plate on the other side of the steel plate and rolling the plate to a thickness of approximately 0.40 mm;
rolling the plate to a thickness of preferably 0.1 to 0.2 mm by using intermediate annealing;
   Most of these steps are known from the usual process for manufacturing stainless steel copper and/or nickel clad products consisting of a core layer of stainless steel with a clad nickel top layer and a clad copper or nickel top layer. However, the use of plating to apply the nickel top layer for the outside of housings and/or lids and the use of mild steel are not known. Both these measures provide a substantial reduction in the cost price of the plate manufactured according to the present invention.

Though the process described above uses plating to deposit the nickel layer, it is also possible to use other depositing methods, such as PVD and CVD.

According to another preferred process, when plating the nickel layer on one side of the steel core layer, on the other side of the core layer a nickel layer is plated as well. This plated nickel layer of approximately 0.1 to 3 μm thick is deposited automatically during the plating of the nickel layer of 10 μm, unless special measures are taken to prevent the deposit of this thin nickel layer. It could therefore be advantageous to have this thin nickel layer deposited, instead of spending the money to prevent this deposit.

Instead of the above used mild steel for the core layer, it is of course possible to use stainless steel, as in the known stainless steel clad products. However, this is more expensive. The use of normal mild steel is a good substitute for stainless steel; the mechanical properties of such mild steels are good enough for the housings and/or lids for button cell batteries to be produced.

The plate producing housings and/or lids for button cell batteries according to the invention is preferably produced as strip. Strip plating provides further cost reduction potential in comparison with piece plating. This is also the case for cladding of strip. For this invention, where the word ‘plate’ has been used, also the word ‘strip’ can be read.

1. Plate for producing housings and/or lids for button cell batteries, comprising
a core layer of steel,
a copper or nickel clad top layer at one side of the core layer and
a nickel top layer at the other side of the core layer, wherein the nickel top layer has been applied by depositing the nickel and wherein the core layer of steel has a thickness from 0.10 to 0.5 mm.

2. Plate according to claim 1, wherein the nickel layer has been applied by plating.

3. Plate according to claim 1, wherein the nickel layer has been applied by Physical Vapour Deposition (PVD) or by Chemical Vapour Deposition (CVD).

4. Plate according to claim 1, wherein the plate consists of a core layer of steel, a copper or nickel clad layer on one surface of the core layer and a deposited nickel layer on the other surface of the core layer.

5. Plate according to claim 1, wherein the plate consists of a core layer of steel, a deposited nickel layer on both surfaces of the core layer and a copper or nickel clad top layer on one of the nickel layers.

6. Plate according to claim 5, wherein the deposited nickel layer between the core layer of steel and the copper or nickel clad top layer is thinner than the deposited nickel top layer.

7. Plate according to claim 1, wherein the core layer consists of mild steel.

8. Plate according to claim 1, wherein the plate has a thickness between 0.1 and 0.5 mm, preferably between 0.1 and 0.2 mm.

9. Housing for a button cell battery fabricated from a plate according to claim 1.

10. Lid for a button cell battery fabricated from a plate according to claim 1.

11. Process for manufacturing a plate according to claim 1, the process comprising the steps of:
a providing step selected from the group consisting of:
(a)providing a hot rolled mild steel plate having a thickness between 0.7 and 5 mm and rolling the hot rolled mild steel plate or: (b) providing a cold rolled mild steel plate;
depositing a nickel layer of 5 to 20 μm, on one side of the mild steel plate and optionally a nickel layer having a maximum thickness of 3 μm on the other side of the mild steel plate;
cladding a copper or nickel layer of 1 to 20% of the thickness of the steel plate on the other side of the steel plate;
rolling and annealing of the steel plate to a thickness of 0.1 and 0.5 mm.

12. Process according to claim 11, wherein the mild steel plate is annealed before the nickel layer is deposited.

13. Process according to claim 11, wherein the mild steel plate with the deposited nickel layer is diffusion annealed after the nickel layer has been deposited.

14. Process according to claim 11, wherein the mild steel plate is annealed before the plate is rolled to its final thickness of 0.1 to 0.5 mm.

15. Process according to claim 11, wherein the nickel is deposited using Physical Vapour Deposition (PVD) or Chemical Vapour Deposition (CVD).

16. Process according to claim 11, wherein the nickel is deposited by plating.

17. Plate according to claim 2, wherein the nickel layer has been applied by electrolytic strip plating.

18. Plate according to claim 7, wherein the core layer consists of mild steel of deep drawing quality.

19. Plate according to claim 8, wherein the plate thickness is between 0.1 and 0.2 mm.

20. Process according to claim 11, wherein the providing step is selected from the group consisting of (a) providing the hot rolled steel plate with a thickness of about 2.1 mm and cold rolled to a thickness of about 1.0 mm or (b) providing the cold rolled mild steel plate with a thickness of about 1.0 mm.

21. Process according to claim 11, wherein the nickel layer deposited on one side of the mild steel is 5 to 10 μm thick and the nickel layer having a maximum thickness of 3 μm is deposited on the other side of the steel plate.

22. Process according to claim 11, wherein the copper or nickel layer clad on the other side of the steel plate is 5 to 10% of the thickness of the steel plate.

23. Process according to claim 14, wherein the mild steel plate is annealed before the plate is rolled to its final thickness of 0.1 to 0.2 mm.

24. Process according to claim 16, wherein the nickel is deposited by electrolytic strip plating.

25. Process according to claim 11, wherein the providing step is selected from the group consisting of: (a) providing the hot rolled mild steel plate having the thickness between 2.1 and 5 mm and cold rolling the hot rolled mild steel plate; or (b) providing the cold rolled mild steel plate.

26. Process according to claim 11, wherein the providing step is selected from the group consisting of: (a) providing the hot rolled mild steel plate having the thickness of 2.1 to 5 mm, pickling the hot rolled steel plate, and cold rolling the hot rolled mild steel plate; or (b) providing the cold rolled mild steel plate.

27. Process according to claim 11, wherein the providing step is selected from the group consisting of: (a) providing the hot rolled mild steel plate of deep drawing quality having a thickness of 0.7 to 5 mm, which thickness is commercially available and pickling the hot rolled steel plate and cold rolling the steel plate to a thickness of approximately 1.0 mm; or (b) providing a cold rolled mild steel plate in deep drawing quality having a thickness of approximately 1.0 mm.

28. Process according to claim 11, wherein the copper or nickel layer clad on the other side of the steel plate is 5 to 10% of the thickness of the steel plate; and
the steel plate is rolled to a thickness of between 0.1 and 0.2 mm and annealed.
